(19) United States
(12) Patent Application Publication
(10) Pub. No.: US 2025/0149209 A1
(43) Pub. Date: May 8, 2025

(54) ELECTRONIC COMPONENT AND FILM FORMING METHOD

(71) Applicant: Murata Manufacturing Co., Ltd., Nagaokakyo-shi (JP)

(72) Inventors: Mitsuru NAKANO, Nagaokakyo-shi (JP); Hiroshi SHIRAKI, Nagaokakyo-shi (JP)

(73) Assignee: Murata Manufacturing Co., Ltd., Nagaokakyo-shi (JP)

(21) Appl. No.: 19/010,399

(22) Filed: Jan. 6, 2025

Related U.S. Application Data
(63) Continuation of application No. PCT/JP2023/044675, filed on Dec. 13, 2023.

(30) Foreign Application Priority Data
May 17, 2023 (JP) 2023-081646

(51) Int. Cl. H01C 1/034; H01C 1/14; H01C 7/04; H01C 17/02

(52) U.S. Cl. CPC H01C 1/034; H01C 1/1413; H01C 7/041; H01C 17/02

(57) ABSTRACT

An electronic component includes a base body and an alumina film covering an outer surface of the base body. The alumina film includes a film-shaped part made of alumina and in contact with the outer surface of the base body, and a particle layer located on the outer surface side of the film-shaped part. The particle layer includes a plurality of alumina particles bonded to the outer surface of the film-shaped part. The average value of the thicknesses of the alumina film including the film-shaped part and the particle layer is 0.05 μm or more and 2.0 μm or less. The interval between the particles is 1.3 μm or less.

### CROSS-REFERENCE TO RELATED APPLICATIONS

This application is a continuation application of PCT International Application No. PCT/JP2023/044675 filed on Dec. 13, 2023, designating the United States of America, which is based on and claims priority to Japanese Patent Application No. 2023-081646 filed on May 17, 2023. The entire disclosures of the above-identified applications, including the specifications, drawings, and claims are incorporated herein by reference in their entirety.

### BACKGROUND ART

Typical electronic components include a base body, an internal electrode, an external electrode, and a protective film. The internal electrode is located inside the base body. The protective film covers the outer surface of the base body. The protective film is an alumina film. The thickness of the protective film is 0.05 μm to 2 μm. The external electrode is stacked on the outer surface of the protective film. The external electrode is electrically connected to the internal electrode.

### SUMMARY

### Problems to be Solved

As recognized by the present inventors, in the typical electronic components described above, the barrier property of the protective film decreases as the film thickness decreases. On the other hand, when the film thickness is increased in order to secure the barrier property, the stress in the protective film increases. Then, in a case where the stress in the protective film is large, there is a possibility that when an external force is applied to the protective film, a crack occurs in the protective film triggered by the external force. Therefore, a technique capable of increasing the film thickness of the protective film while suppressing the occurrence of a crack in the protective film is desired.

### Solutions to the Problems

An electronic component including: a base body; and an alumina film covering an outer surface of the base body, wherein the alumina film includes: a film-shaped part made of alumina and being in contact with the outer surface of the base body; and a particle layer located on a side closer to an outer surface of the film-shaped part, the particle layer includes a plurality of particles made of alumina, the plurality of particles being bonded to an outer surface of the film-shaped part, the alumina film including the film-shaped part and the particle layer has an average value of thicknesses of 0.05 μm or more and 2.0 μm or less inclusive, and the particles have an interval of 1.3 μm or less.

A film forming method for forming an alumina film on an outer surface of a base body,
the film forming method including: a charging step of charging the base body into a first chamber that is capable of heating an internal atmosphere; a misting step of forming a raw material that is liquid and contains an aluminum atom and an oxygen atom into mist with an ultrasonic wave in a second chamber; a supply step of supplying the misted raw material an inside of the second chamber into the first chamber together with a carrier gas; and a first heating step of heating an inside of the first chamber to a first temperature while performing the supply step, and further a second heating step of heating the inside of the first chamber to a second temperature defined as a temperature lower than the first temperature while performing the supply step after the first heating step.

### Advantageous Effect of the Disclosure

According to the configuration mentioned above, the thickness of the alumina film can be increased while suppressing the occurrence of a crack in the alumina film.

### BRIEF EXPLANATION OF DRAWINGS

FIG. 1 is a perspective view of an electronic component.

FIG. 2 is a side view of the electronic component.

FIG. 3 is a sectional view taken along line 3-3 in FIG. 2.

FIG. 4 is an end view of the vicinity of an alumina film, taken along line 4-4 in FIG. 2.

FIG. 5 is a measurement result of a scratch strength test.

FIG. 6 is an explanatory diagram illustrating a method of manufacturing an electronic component.

FIG. 7 is an explanatory diagram illustrating a method of manufacturing an electronic component.

FIG. 8 is an explanatory diagram illustrating a method of manufacturing an electronic component.

FIG. 9 is an explanatory diagram illustrating a method of manufacturing an electronic component.

### DETAILED DESCRIPTION

### Exemplary Embodiment of Electronic Component

Hereinafter, an exemplary embodiment of the electronic component will be described with reference to the drawings. In the drawings, sometimes a component is illustrated while enlarged for the sake of easy understanding. In some cases, the dimension ratio of a component differs from an actual dimension ratio or a dimension ratio in another drawing.

### <Electronic Component>

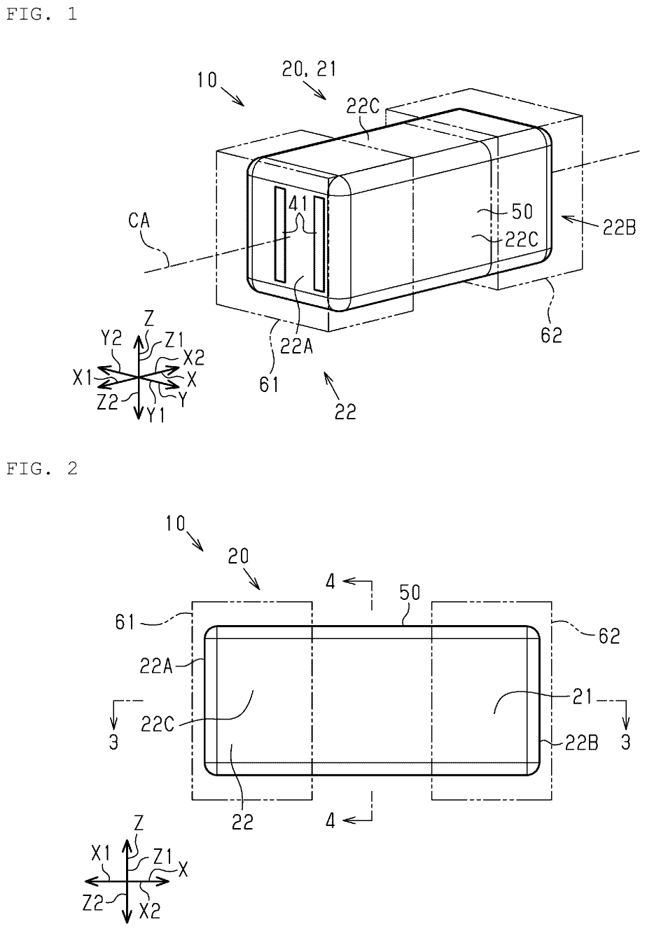

As illustrated in FIG. 1, an electronic component 10 is, for example, a surface mount negative characteristic thermistor component to be mounted on a circuit board or the like. It is to be noted that the negative characteristic thermistor component has a characteristic that the resistance value is decreased as the temperature is increased. The electronic component 10 includes a base body 20. The base body 20 has a substantially quadrangular prism shape and has a central axis CA. Hereinafter, an axis extending along the central axis CA is referred to as a first axis X. One of the axes orthogonal to the first axis X is defined as a second axis Y. Further, an axis that is orthogonal to both the first axis X and the second axis Y is defined as a third axis Z. In addition, one of the directions along the first axis X is defined as a first positive direction X1, and the direction opposite to the first positive direction X1, of the directions along the first axis X, is defined as a first negative direction X2. In addition, one of the directions along the second axis Y is defined as a second positive direction Y1, and the direction opposite to the second positive direction Y1, of the directions along the second axis Y, is defined as a second negative direction Y2. Further, one of the directions along the third axis Z is defined as a third positive direction Z1, and a direction opposite to the third positive direction Z1, of the directions along the third axis Z, is defined as a third negative direction Z2.

An outer surface 21 of the base body 20 has six planes 22. The term “surface” of the base body 20 as used herein refers to a part that can be observed as a surface when the entire base body 20 is observed. More specifically, for example, when there are such minute irregularities or steps that fail to be found unless a part of the base body 20 is enlarged and then observed with a microscope or the like, the surface is expressed as a plane or a curved surface. The six planes 22 face different directions. The six planes 22 are roughly divided into a first end surface 22A that faces in the first positive direction X1, a second end surface 22B that has in the first negative direction X2, and four side surfaces 22C. The four side surfaces 22C are a surface facing the third positive direction Z1, a surface facing the third negative direction 22, a surface facing the second positive direction Y1, and a surface facing the second negative direction Y2, respectively.

The arithmetic average roughness (Ra) of the outer surface 21 of the base body 20 is 0.5 μm or less. The arithmetic average roughness of the outer surface 21 of the base body 20 is measured by a laser microscope. For example, in the manufacturing process of the electronic component 10, in a stage where the outer surface 21 is exposed, a length of 300 μm or more is linearly scanned and measured at an arbitrary position of the outer surface 21.

In the outer surface 21 of the base body 20, a boundary portion between two adjacent planes 22 and a boundary portion between three adjacent planes 22 are curved surfaces. That is, corners of the base body 20 are so-called round chamfered.

As illustrated in FIG. 2, the base body 20 has a dimension in the direction along the first axis X larger than a dimension in the direction along the third axis Z. Furthermore, as illustrated in FIG. 1, the base body 20 has a dimension in the direction along the first axis X larger than the dimension in the direction along the second axis Y. The material of the base body 20 is a semiconductor. Specifically, the material of the base body 20 is a ceramic obtained by firing a metal oxide containing at least one of Mn, Fe, Ni, Co, Ti, Ba, Al, and Zn as a component.

As illustrated in FIG. 3, the electronic component 10 includes two first internal electrodes 41 and two second internal electrodes 42. The first internal electrode 41 and the second internal electrode 42 are located inside the base body 20.

The material of the first internal electrode 41 is a conductive material. For example, the material of the first internal electrode 41 is palladium. The material of the second internal electrode 42 is the same as the material of the first internal electrode 41.

The first internal electrode 41 has a rectangular plate shape. The first internal electrode 41 has a principal surface orthogonal to the second axis Y. The second internal electrode 42 has the same rectangular plate shape as the first internal electrode 41. The second internal electrode 42 has a principal surface orthogonal to the second axis Y, as with the first internal electrode 41.

The dimension of the first internal electrode 41 in the direction along the first axis X is smaller than the dimension of the base body 20 in the direction along the first axis X. As illustrated in FIG. 1, the dimension of the first internal electrode 41 in the direction along the third axis Z is approximately ⅔ of the dimension of the base body 20 in the direction along the third axis Z. The dimension of the second internal electrode 42 in each of the directions is the same as that of the first internal electrode 41.

As illustrated in FIG. 3, the first internal electrodes 41 and the second internal electrodes 42 are located in a staggered manner in the direction along the second axis Y. That is, a total of four internal electrodes are alternately arranged in the order of the first internal electrode 41, the second internal electrode 42, the first internal electrode 41, and the second internal electrode 42 from the side surface 22C facing the second positive direction Y1 toward the second negative direction Y2. According to the exemplary embodiment, each of the internal electrodes has an equal distance therebetween in the direction along the second axis Y.

As illustrated in FIG. 1, the two first internal electrodes 41 and the two second internal electrodes 42 are both located at the center of the base body 20 in the direction along the third axis Z. On the other hand, as illustrated in FIG. 3, the first internal electrodes 41 are located deviated to the first positive direction X1. The second internal electrodes 42 are located deviated to the first negative direction X2.

Specifically, the end of the first internal electrode 41 on the first positive direction X1 side coincides with the end of the base body 20 on the first positive direction X1 side. The end of the first internal electrode 41 on the first negative direction X2 side is located inside the base body 20 and does not reach the end of the base body 20 on the first negative direction X2 side. On the other hand, the end of the second internal electrode 42 on the first negative direction X2 side coincides with the end of the base body 20 on the first negative direction X2 side. The end of the second internal electrode 42 on the first positive direction X1 side is located inside the base body 20 and does not reach the end of the base body 20 on the first positive direction X1 side.

As illustrated in FIG. 3, the electronic component 10 includes an alumina film 50. The alumina film 50 covers the outer surface 21 of the base body 20. According to the present exemplary embodiment, the alumina film 50 covers the entire region of the outer surface 21 of the base body 20. In the present exemplary embodiment, the alumina film 50 indicates that the main component of the film is alumina. Specifically, the alumina film 50 is a film in which the total of the aluminum atom and the atomic percent of the oxygen atom contained in the film is 80% or more. According to this exemplary embodiment, the alumina film 50 contains a hydrogen atom and a carbon atom.

The electronic component 10 includes a first external electrode 61 and a second external electrode 62. The first external electrode 61 is located on the outer surface of the alumina film 50. The first external electrode 61 includes a first underlying electrode 61A and a first metal layer 61B. The first underlying electrode 61A is stacked on the alumina film 50 in a portion including the first end surface 22A of the outer surface 21 of the base body 20. The first underlying electrode 61A is a five-face electrode that covers the first end surface 22A of the base body 20 and parts of the four side surfaces 22C thereof in the first positive direction X1. According to this exemplary embodiment, the material of the first underlying electrode 61A is copper and glass. In addition, the first underlying electrode 61A is a sintered body.

As illustrated in FIG. 3, the first metal layer 61B covers the first underlying electrode 61A from the outside. Thus, the first metal layer 61B is stacked on the first underlying electrode 61A. In addition, a part of the first metal layer 61B is protruded from the first underlying electrode 61A. That is, a part of the outer edge of the first metal layer 61B directly covers the alumina film 50 without the first underlying electrode 61A interposed therebetween. Although not illustrated in the drawing, the first metal layer 61B has a two-layer structure of a nickel layer and a tin layer in this order from the first underlying electrode 61A side.

The second external electrode 62 includes a second underlying electrode 62A and a second metal layer 62B. The second underlying electrode 62A is stacked on the alumina film 50 in a portion including the second end surface 22B of the outer surface 21 of the base body 20. The second underlying electrode 62A is a five-face electrode that covers the second end surface 22B of the base body 20 and parts of the four side surfaces 22C thereof in the first negative direction X2. According to this exemplary embodiment, the material of the second underlying electrode 62A is the same as the material of the first external electrode 61 and is copper and glass. In addition, as with the first underlying electrode 61A, the second underlying electrode 62A is a sintered body.

The second metal layer 62B covers the second underlying electrode 62A from the outside. Thus, the second metal layer 62B is stacked on the second underlying electrode 62A. In addition, a part of the second metal layer 62B is protruded from the second underlying electrode 62A. That is, a part of the outer edge of the second metal layer 62B directly covers the alumina film 50 without the second underlying electrode 62A interposed therebetween. Although not illustrated in the drawing, the second metal layer 62B has, as with the first metal layer 61B, a two-layer structure of a nickel layer and a tin layer in this order from the second underlying electrode 62A.

The second external electrode 62 does not reach the first external electrode 61 on the side surface 22C, and is disposed away from the first external electrode 61 in the direction along the first axis X. On the side surface 22C of the base body 20, the first external electrode 61 and the second external electrode 62 are not stacked and the alumina film 50 is exposed in the central portion in the direction along the first axis X. In FIGS. 1 to 3, the first external electrode 61 and the second external electrode 62 are indicated by two-dot chain lines.

The first external electrode 61 and the end of the first internal electrode 41 on the first positive direction X1 side are connected via a first penetrating portion 71 penetrating the alumina film 50. Thus, the first external electrode 61 is electrically connected to the first internal electrode 41. Although details will be described later, the first penetrating portion 71 is formed such that the palladium constituting the first internal electrode 41 extends to the first external electrode 61 side in the manufacturing process of the electronic component 10.

The second external electrode 62 and the end of the second internal electrode 42 on the first negative direction X2 side are connected via a second penetrating portion 72 penetrating the alumina film 50. Thus, the second external electrode 62 is electrically connected to the second internal electrode 42. Similarly to the first penetrating portion 71, the second penetrating portion 72 is also formed such that the palladium constituting the second internal electrode 42 extends to the second external electrode 62 side in the manufacturing process of the electronic component 10. In FIG. 3, the first internal electrode 41 and the first penetrating portion 71 are illustrated as separate members having a boundary; however, actually, there is no clear boundary therebetween. In this respect, the same applies to the second penetrating portion 72. In FIG. 1, illustration of the first penetrating portion 71 is omitted.

### <Alumina Film>

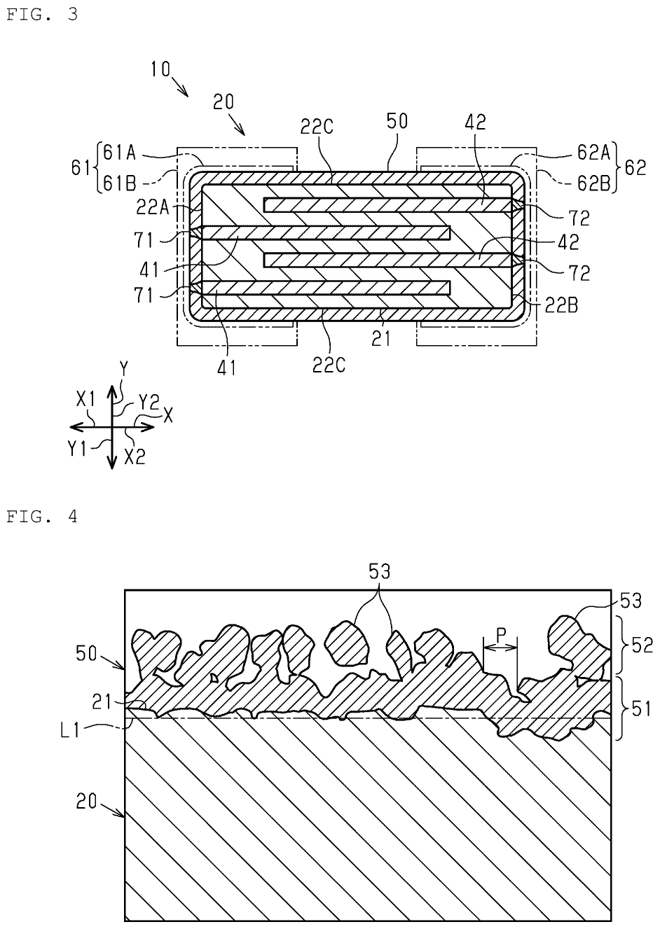

As illustrated in FIG. 4, the alumina film 50 includes a film-shaped part 51 and a particle layer 52. The film-shaped part 51 is made of alumina. The film-shaped part 51 is a portion where alumina is present without any break when the film-shaped part 51 traces along the shape of the outer surface 21 of the base body 20 on the outer surface 21. The film-shaped part 51 is in contact with the outer surface 21 of the base body 20. More specifically, the film-shaped part 51 covers the entire outer surface 21 of the base body 20.

The particle layer 52 is located on the outer surface side with respect to the film-shaped part 51. The particle layer 52 contains a plurality of particles 53 of alumina. The plurality of particles 53 are bonded to the outer surface of the film-shaped part 51. In FIG. 4, only some of the particles 53 are denoted by reference numerals. In addition, in FIG. 4, some of the particles 53 are separated from the film-shaped part 51, but in a case of viewing from the end surface shifted in the depth direction of the paper surface in FIG. 4, the particles 53 are bonded to the outer surface of the film-shaped part 51.

Each particle 53 has various shapes. For example, it is assumed that the alumina film 50 is viewed from the end surface in a section orthogonal to any plane 22 of the base body 20. At this time, the particle 53 has an elliptical shape or a distorted shape due to joining of the plurality of particles 53.

The interval P between the particles 53 is 1.3 μm or less. In the present exemplary embodiment, the maximum length of the interval P between the particles 53 is 0.51 μm. The interval P between the particles 53 is measured as follows. First, a section orthogonal to any of the planes 22 of the base body 20 and including the alumina film 50 is photographed with an electron microscope. Next, an approximate straight line L1 with respect to the outer surface 21 is drawn for the photographed image. The approximate straight line L1 can be obtained by, for example, a least squares method. The shortest distance between the particles 53 in the direction parallel to the approximate straight line L1 is defined as an interval P between the particles 53. In FIG. 4, only the maximum interval P is illustrated as a representative.

The average value of the thicknesses of the alumina film 50 including the film-shaped part 51 and the particle layer 52 is 0.05 μm or more and 2.0 μm or less. The average value of the thicknesses of the alumina film 50 is the total of the average value of the thicknesses of the film-shaped part 51 and the average value of the thicknesses of the particle layer 52. In the present exemplary embodiment, the average value of the thicknesses of the alumina film 50 is 0.57 nm.

The average value of the thicknesses of the film-shaped part 51 is 0.3 μm. The thickness of the film-shaped part 51 is the shortest distance from the position of the film-shaped part 51 on the outer surface 21 side of the base body 20 to the outer surface of the film-shaped part 51. The average value of the thicknesses of the film-shaped part 51 is measured as follows.

First, a section orthogonal to any of the planes 22 of the base body 20 and including the alumina film 50 is photographed with an electron microscope. Next, a range in a direction along the outer surface of the film-shaped part 51 is specified for the photographed image. In this range, the sectional area of the film-shaped part 51 is calculated by image processing for a measurement range of at least 5 μm or more. Then, the calculated sectional area of the film-shaped part 51 in the measurement range is divided by the length, which is the measurement range, to calculate the thickness of the film-shaped part 51 in the section. This is taken as the average value of the thicknesses of the film-shaped part 51.

The average value of the thicknesses of the particle layer 52 is 0.27 μm. The average value of the thicknesses of the particle layer 52 is calculated as follows. A section orthogonal to any of the planes 22 of the base body 20 and including the alumina film 50 is photographed with an electron microscope. Next, a range in a direction along the outer surface of the film-shaped part 51 is specified for the photographed image. In this range, the total sectional area of the particles 53 is calculated by image processing for a measurement range of at least 5 μm or more. Then, the total of the calculated sectional areas of the particles 53 in the measurement range is divided by the length, which is the measurement range, to calculate the thickness of the particle layer 52 in the section. This is taken as the average value of the thicknesses of the particle layer 52. In the particle layer 52, there are a portion where the particle 53 is present and a portion where the particle 53 is not present in the measurement range. At a portion where the particle 53 is not present, the thickness of the particle layer 52 is locally 0. Therefore, the average value of the thicknesses of the particle layer 52 calculated by the above method is a smaller value than the particle size of each particle 53.

The ratio of the average value of the thicknesses of the particle layer 52 to the average value of the thicknesses of the alumina film 50 is 20% or more and 70% or less. Specifically, according to this exemplary embodiment, the ratio of the average value of the thicknesses of the particle layer 52 to the average value of the thicknesses of the alumina film 50 is about 47.4%.

### <Scratch Strength Test of Alumina Film>

Here, a test for measuring the scratch strength of the alumina film 50 was performed. In this test, the “scratch strength” was defined as the external force when the outer surface of the alumina film 50 is scratched and breakage occurs to the inside of the alumina film 50.

First, a plurality of samples were prepared. In each sample, an alumina film 50 including a film-shaped part 51 and a particle layer 52 is formed on a silicon board. Then, the thickness of the alumina film 50 was changed within a range of 0.05 μm to 0.95 μm for each sample.

In this scratch strength test, a sample was fixed on a table, and a probe was brought into close contact with the outer surface of the alumina film 50 of the sample. Then, the table on which the sample was fixed was moved at a constant speed while increasing the pressing strength of the probe against the alumina film 50. In this case, the scratch strength was defined as the pressing strength of the inside of the alumina film 50, specifically when a scratch occurred that exposed the silicon board.

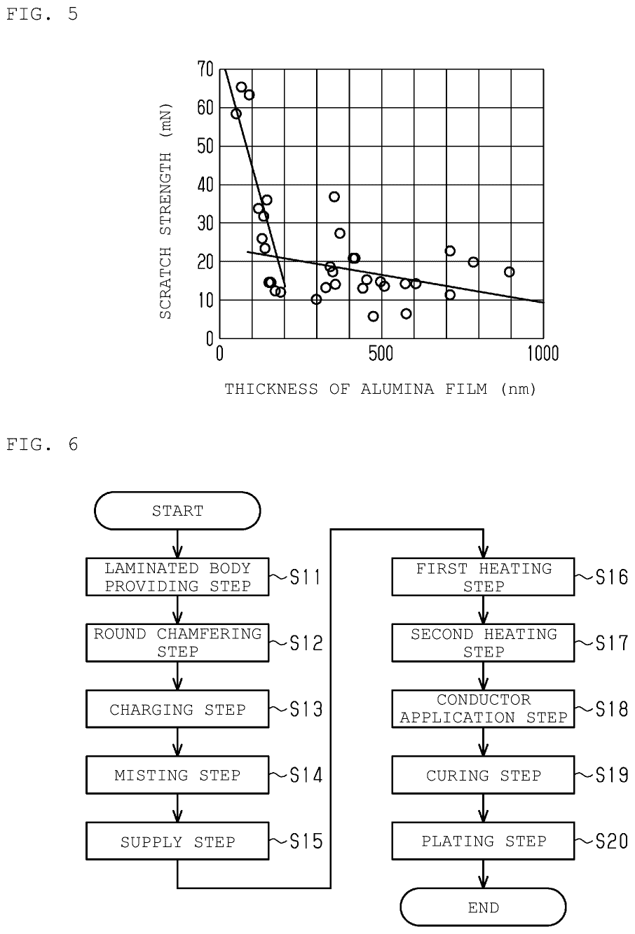

As illustrated in FIG. 5, the scratch strength tended to increase as the thickness of the alumina film 50 decreased. In particular, when the thickness of the alumina film 50 exceeded about 0.2 μm, the scratch strength remained at a low level of approximately less than 20 mN. On the other hand, when the thickness of the alumina film 50 was about 0.2 μm or less, the scratch strength rapidly increased as the thickness decreased. Therefore, it was found that the thickness of the alumina film 50 is preferably 0.2 μm or less from the viewpoint of preventing occurrence of a crack.

### <Method of Manufacturing Electronic Component>

Next, the method for manufacturing the electronic component 10 will be described.

As illustrated in FIG. 6, the method for manufacturing the electronic component 10 includes a laminated body providing step S11, a round chamfering step S12, a charging step S13, a misting step S14, a supply step S15, a first heating step S16, and a second heating step S17. The method for manufacturing the electronic component 10 further includes a conductor application step S18, a curing step S19, and a plating step S20.

First, in forming the base body 20, a laminate body is prepared in the laminated body providing step S11. The laminate body at this stage is in a state before round chamfering, and has a rectangular parallelepiped shape having the six planes 22. For example, first, a plurality of ceramic sheets to be the base body 20 are provided. Each of the sheets has a thin plate shape. A conductive paste to be the first internal electrode 41 is laminated on the sheet. A ceramic sheet to be the base body 20 is laminated on the laminated paste. A conductive paste to be the second internal electrode 42 is laminated on the sheet. In this manner, the ceramic sheet and the conductive paste are laminated. Then, the laminated sheets are subjected to pressure bonding in the stacking direction by means such as die pressing. Thereafter, the sheets subjected to the pressure bonding are cut into a predetermined size to form an unfired laminated body. Thereafter, the unfired laminated body is fired at a high temperature to provide a laminated body.

Next, the round chamfering step S12 is performed. In the round chamfering step S12, the laminate body provided in the laminated body providing step S11 is round chamfered. By this step, the base body 20 in which the corner portion is round chamfered is obtained.

Next, the charging step S13 to the second heating step S17 are sequentially performed. The film forming apparatus 100 is used from the charging step S13 to the second heating step S17.

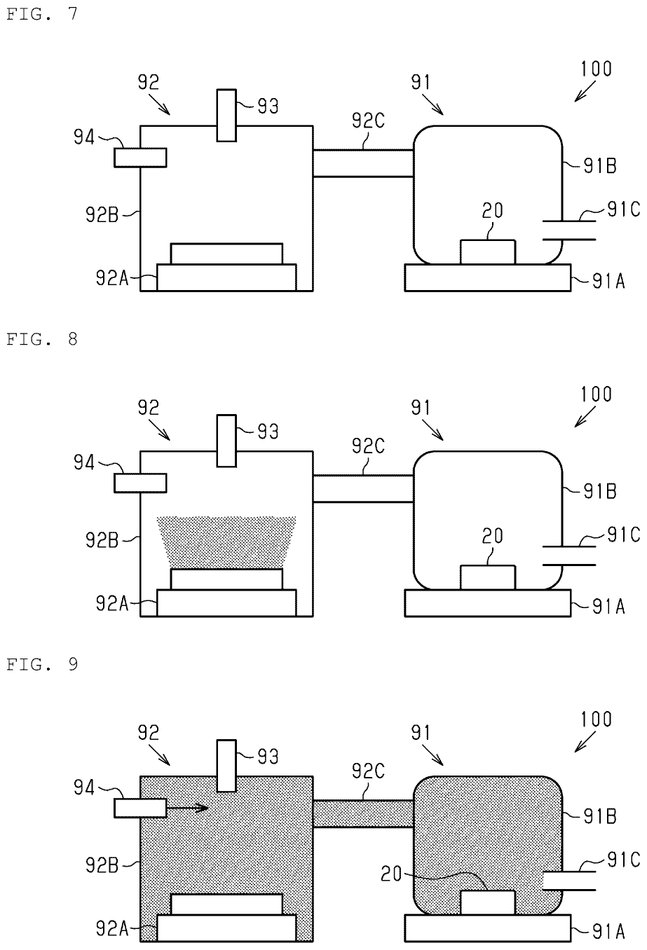

As illustrated in FIG. 7, the film forming apparatus 100 includes a first chamber 91. The first chamber 91 can heat the internal atmosphere. Specifically, the first chamber 91 includes a heater 91A, a container main body 91B, and a discharge passage 91C. The heater 91A is located at the bottom of the container main body 91B. By driving the heater 91A, the atmosphere in the container main body 91B is heated. The discharge passage 91C is connected to the container main body 91B. The inside of the container main body 91B communicates with the outside through a discharge passage 91C.

The film forming apparatus 100 includes a second chamber 92, a liquid supply nozzle 93, and a gas supply nozzle 94. The second chamber 92 includes an ultrasonic wave generator 92A, a container main body 92B, and a communication passage 92C. The ultrasonic wave generator 92A is located at the bottom of the container main body 92B. By driving the ultrasonic wave generator 92A, the liquid supplied into the container main body 92B can be made into a mist-like. The communication passage 92C is connected to the container main body 91B of the first chamber 91 and the container main body 92B of the second chamber 92. That is, the inside of the container main body 92B of the second chamber 92 communicates with the inside of the container main body 91B of the first chamber 91 via the communication passage 92C. The liquid supply nozzle 93 can supply a liquid raw material into the container main body 92B. The gas supply nozzle 94 can supply the carrier gas into the container main body 92B.

As illustrated in FIG. 6, the charging step S13 is performed. As illustrated in FIG. 7, in the charging step S13, the base body 20 is charged into the first chamber 91 of the film forming apparatus 100. Then, by driving the heater 91A of the first chamber 91, the atmosphere in the first chamber 91 is heated.

Next, as illustrated in FIG. 6, the misting step S14 is performed. As illustrated in FIG. 8, in the misting step S14, a liquid raw material is put into the second chamber 92 via the liquid supply nozzle 93. The ultrasonic wave generator 92A is driven to make the raw material into mist-like with ultrasonic waves. The term “mist-like” refers to a state in which droplets having a particle size of 10 μm or less are formed. The raw material include aluminum acetylacetonate, methanol, and water. That is, the raw material contains an aluminum atom and an oxygen atom. Further, the raw material contains a carbon atom and a hydrogen atom.

Next, as illustrated in FIG. 6, the supply step S15 is performed. As illustrated in FIG. 9, in the supply step S15, the carrier gas is supplied into the second chamber 92 via the gas supply nozzle 94. As a result, the mist-like raw material is supplied from the inside of the second chamber 92 into the first chamber 91 together with the carrier gas. The carrier gas is, for example, an inert gas such as oxygen, ozone, nitrogen, or argon. The carrier gas may be a reducing gas such as a hydrogen gas or a forming gas. The excess carrier gas and the excess raw material supplied into the first chamber 91 are discharged to the outside of the film forming apparatus 100 through the discharge passage 91C.

Next, as illustrated in FIG. 6, the first heating step S16 is performed. In the first heating step S16, the atmosphere in the first chamber 91 is heated while performing the supply step S15. Specifically, in the first heating step S16, the heater 91A is driven to heat the inside of the first chamber 91 to the first temperature. By heating, the particle size of the mist flowing into the first chamber 91 from the second chamber 92 is refined. The temperature in the first chamber 91 at this time is, for example, several hundred degrees. In the first heating step S16, the mist-like raw material is supplied to the base body 20 while being vaporized. As a result, the dense film-shaped part 51 is formed on the outer surface 21 of the base body 20.

Next, the second heating step S17 is performed. In the second heating step S17, after the first heating step S16, the inside of the first chamber 91 is heated to a second temperature determined as a temperature lower than the first temperature while performing the supply step S15. The second temperature is, for example, about 100 degrees lower than the first temperature. As described above, in a case where the inside of the first chamber 91 is set to the second temperature in the second heating step S17, the particle size of the mist-like raw material is larger than that in the first heating step S16. That is, in the second heating step S17, the particle size of the mist in the first chamber 91 is larger than that in the first heating step S16. The mist having such a large particle size adheres to the film-shaped part 51 to form the particles 53. In this step, the plurality of particles 53 are formed on the film-shaped part 51, and the particle layer 52 which is a part of the alumina film 50 is formed.

In addition, the composition ratio of the atoms contained in the raw material is made constant during execution of the misting step S14, the supply step S15, the first heating step S16, and the second heating step S17 described above. That is, the composition ratio of the mist formed from the raw material is substantially the same in any time zone during the above step. The steps from the charging step S13 to the second heating step S17 are a film forming method of forming the alumina film 50 on the outer surface 21 of the base body 20.

Next, the conductor application step S18 is performed. In the conductor application step S18, a conductor paste is applied to two portions of the surface of the alumina film 50, that is, a portion including a portion covering the first end surface 22A of the base body 20 and a portion including a portion covering the second end surface 22B of the base body 20. Specifically, the conductor paste is applied to cover the alumina film 50 on the entire region of the first end surface 22A and a part of the four side surfaces 22C. Furthermore, the conductor paste is applied to cover the alumina film 50 on the entire region of the second end surface 22B and a part of the four side surfaces 22C.

Next, the curing step S19 is performed. Specifically, in the curing step S19, the base body 20 is heated. In the curing step S19, the conductor paste applied in the conductor application step S18 is fired to form the first underlying electrode 61A and the second underlying electrode 62A.

In the present exemplary embodiment, at the time of heating in the curing step S19, the palladium contained on the side with the first internal electrodes 41 is attracted toward the side with first underlying electrode 61A containing copper by the Kirkendall effect caused from the difference in diffusion rate between the first internal electrodes 41 and the first underlying electrode 61A. As a result, the first penetrating portion 71 extends through the alumina film 50 from the first internal electrode 41 toward the first underlying electrode 61A. As a result, the first internal electrode 41 and the first underlying electrode 61A are connected. In this respect, the same applies to the second penetrating portion 72 connecting the second internal electrode 42 and the second underlying electrode 62A.

Next, the plating step S20 is performed. Parts of the first underlying electrode 61A and second underlying electrode 62A are subjected to electroplating. As a result, the first metal layer 61B is formed on the surface of the first underlying electrode 61A. In addition, the second metal layer 62B is formed on the surface of the second underlying electrode 62A. Although not illustrated in the drawing, the first metal layer 61B and the second metal layer 62B are electroplated with two kinds, nickel and tin, to form a two-layer structure. In this way, the electronic component 10 is formed.

### Advantageous Effects of Present Exemplary Embodiment

(1) According to the exemplary embodiment mentioned above, the thickness of the alumina film 50 as a whole is such that the barrier property can be sufficiently secured. The alumina film 50 includes the film-shaped part 51 and the particle 53. According to this configuration, the stress in the alumina film 50 can be released between the particle 53 and the other particle 53 as compared with the case where the entire alumina film 50 is constituted by the film-shaped part 51. Therefore, since it is possible to prevent the stress from locally increasing in the alumina film 50, the occurrence of a crack can still be suppressed when an external force acts. In addition, since the interval P between the particles 53 is 1.3 μm or less, it is possible to prevent the impact from concentrating on one particle 53 when an impact or the like is applied from the outside of the layer of particles 53. That is, with the interval P between the particles 53, the base body 20 can be protected.

(2) In the exemplary embodiment described above, the ratio of the average value of the thicknesses of the particle layer 52 to the average value of the thicknesses of the alumina film 50 is 20% or more. According to this configuration, the stress relaxation effect of the alumina film 50 by the particle layer 52 can be sufficiently obtained. In the exemplary embodiment mentioned above, the ratio of the average value of the thicknesses of the particle layer 52 to the average value of the thicknesses of the alumina film 50 is 70% or less. According to this configuration, the barrier property by the film-shaped part 51 can be sufficiently obtained.

(3) In the exemplary embodiment mentioned above, the arithmetic average roughness of the outer surface 21 of the base body 20 is 0.5 μm or less. In a case where the arithmetic average roughness of the outer surface 21 of the base body 20 is correspondingly large, the irregularities of the outer surface 21 of the base body 20 may also be reflected on the outer surface of the film-shaped part 51. As described above, in a case where the outer surface of the film-shaped part 51 have irregularities, the particles 53 are accumulated in the recesses of the film-shaped part 51 at the time of manufacturing, and the particles 53 are less likely to be uniformly positioned on the outer surface of the film-shaped part 51. According to the configuration mentioned above, since the arithmetic average roughness of the outer surface 21 of the base body 20 is correspondingly small, it is possible to suppress the particles 53 from being non-uniformly positioned on the outer surface of the film-shaped part 51 as described above.

(4) According to the exemplary embodiment mentioned above, the composition ratio of the atoms contained in the raw material is constant in the misting step S14, the supply step S15, the first heating step S16, and the second heating step S17. According to this configuration, the composition ratio does not change in both the step of forming the film-shaped part 51 and the step of forming the particle 53. Since the film-shaped part 51 and the particle 53 have substantially the same composition ratio, a boundary is less likely to occur between these members, and the particle 53 is less likely to fall off from the film-shaped part 51.

### Modification Examples

The exemplary embodiment mentioned above and the following modification examples can be implemented in combination within a range that is not technically contradictory.
In the exemplary embodiment, the electronic component 10 is not limited to a negative characteristic thermistor component. For example, the electronic component 10 may be a piezoelectric component, a multilayer ceramic capacitor, an inductor, or the like.
In the exemplary embodiment mentioned above, the numbers of the first internal electrodes 41 and the second internal electrodes 42 are not limited to the example of the exemplary embodiment mentioned above. The number of the first internal electrodes 41 may be less than or more than two. In this respect, the same applies to the second internal electrodes 42.
In the exemplary embodiment mentioned above, the material of the first underlying electrode 61A and the material of the second underlying electrode 62A are not limited to the examples of the exemplary embodiment mentioned above. For example, the material of the first underlying electrode 61A and the material of the second underlying electrode 62A may be a mixture of silver and glass.
In the exemplary embodiment mentioned above, the alumina film 50 may not cover the entire base body 20. The alumina film 50 may cover at least a part of the outer surface 21 of the base body 20.
In the exemplary embodiment mentioned above, the interval P between the particles 53 on the alumina film 50 is not limited to the example of the exemplary embodiment mentioned above as long as it is 1.3 μm or less.
In the exemplary embodiment mentioned above, the average value of the thicknesses of the alumina film 50 is not limited to the example of the exemplary embodiment mentioned above as long as it is 0.05 μm or more and 2.0 μm or less.
In the exemplary embodiment mentioned above, the ratio of the average value of the thicknesses of the particle layer 52 to the average value of the thicknesses of the alumina film 50 may be less than 20% or more than 70%. As the proportion of the particle layer 52 in the alumina film 50 is larger, suppression of stress in the alumina film 50 can be expected. In addition, as the proportion of the film-shaped part 51 in the alumina film 50 increases, the barrier property of the alumina film 50 can be expected to be improved.
In the exemplary embodiment mentioned above, the alumina film 50 may further contain another atom in addition to the oxygen atom and the aluminum atom. For example, the alumina film 50 may contain another atom other than a carbon atom and a hydrogen atom. Further, the alumina film 50 may not contain a carbon atom and a hydrogen atom.
In the exemplary embodiment mentioned above, the chemical substance of the raw material adopted in the misting step S14, the supply step S15, the first heating step S16, and the second heating step S17 is not limited to the example of the exemplary embodiment mentioned above. For example, the raw material may be an organic salt containing aluminum, an organic solvent, or the like. The raw material may or may not contain water.
In the exemplary embodiment mentioned above, the composition ratio of the atoms contained in the raw material may be changed during execution of the misting step S14, the supply step S15, the first heating step S16, and the second heating step S17. In a case where the composition ratio of the raw material is changed, the alumina film 50 may still be configured in such a manner that the total of the atomic percents of the aluminum atom and the oxygen atom is 80% or more, with the main component being composed of alumina.
In the exemplary embodiment mentioned above, the arithmetic average roughness of the outer surface 21 of the base body 20 is not limited to the example of the exemplary embodiment mentioned above. For example, the arithmetic average roughness of the outer surface 21 of the base body 20 may be larger than 0.5 μm.
In the exemplary embodiment mentioned above, the film-shaped part 51 and the particle layer 52 are formed by the difference in heating temperature between the first heating step S16 and the second heating step S17, but the film-shaped part 51 and the particle layer 52 may be formed by other methods. For example, the film-shaped part 51 and the particle layer 52 may be formed by varying the frequency of the ultrasonic wave from the ultrasonic wave generator 92A. In the exemplary embodiment mentioned above, the film forming method of the alumina film 50 is not limited to the method for attaching the mist-like raw material to the base body 20.

### <Supplementary Note>

Technical ideas that can be derived from the exemplary embodiments and modification examples mentioned above will be described below.

[1] An electronic component including: a base body; and an alumina film covering an outer surface of the base body, wherein the alumina film includes: a film-shaped part made of alumina and being in contact with the outer surface of the base body; and a particle layer located on a side closer to an outer surface of the film-shaped part, the particle layer includes a plurality of particles made of alumina and being bonded to an outer surface of the film-shaped part,
the alumina film including the film-shaped part and the particle layer has an average value of thicknesses of 0.05 μm or more and 2.0 μm or less inclusive, and the particles have an interval of 1.3 μm or less.

[2] The electronic component according to [1], wherein a ratio of the average value of the thicknesses of the particle layer to the average value of the thicknesses of the alumina film is 20% or more and 70% or less inclusive.

[3] The electronic component according to [1] or [2], wherein an outer surface of the base body has an arithmetic average roughness of 0.5 μm or less.

[4] A film forming method for forming an alumina film on an outer surface of a base body,
the film forming method including: a charging step of charging the base body into a first chamber that is capable of heating an internal atmosphere; a misting step of forming a raw material that is liquid and contains an aluminum atom and an oxygen atom into mist with an ultrasonic wave in a second chamber; a supply step of supplying the misted raw material from an inside of the second chamber into the first chamber together with a carrier gas; and a first heating step of heating an inside of the first chamber to a first temperature while performing the supply step, and further a second heating step of heating the inside of the first chamber to a second temperature defined as a temperature lower than the first temperature while performing the supply step after the first heating step.

[5] The film forming method according to [4], wherein a composition ratio of atoms contained in the raw material is made constant during execution of the misting step, the supply step, the first heating step, and the second heating step.

### DESCRIPTION OF REFERENCE SYMBOLS

10: Electronic component
20: Base body
21: Outer surface
41: First internal electrode
42: Second internal electrode
50: Alumina film
51: Film-shaped part
52: Particle layer
53: Particle
61: First external electrode
62: Second external electrode

1. An electronic component comprising:
a base body; and
an alumina film covering an outer surface of the base body, wherein
the alumina film includes: a film-shaped part made of alumina and being in contact with the outer surface of the base body; and a particle layer located on a side closer to an outer surface of the film-shaped part,
the particle layer includes a plurality of particles made of alumina, the plurality of particles being bonded to an outer surface of the film-shaped part,
the alumina film including the film-shaped part and the particle layer has an average value of thicknesses of 0.05 μm or more and 2.0 μm or less inclusive, and
the particles have an interval of 1.3 μm or less.

2. The electronic component according to claim 1, wherein a ratio of the average value of the thicknesses of the particle layer to the average value of the thicknesses of the alumina film is 20% or more and 70% or less inclusive.

3. The electronic component according to claim 1, wherein an outer surface of the base body has an arithmetic average roughness of 0.5 μm or less.

4. The electric component according to claim 1, wherein the alumina film covers an entire region of the outer surface of the base body.

5. The electric component according to claim 1, wherein the alumina film is a film in which the total of the aluminum atom and the atomic percent of the oxygen atom contained in the film is 80% or more.

6. The electric component according to claim 1, wherein the alumina film contains a hydrogen atom and a carbon atom.

7. The electric component according to claim 1, wherein a maximum length of the interval between the particles is 0.51 μm or more.

8. The electric component according to claim 1, wherein the base body is negative characteristic thermistor component.

9. The electric component according to claim 1, further comprising underlying electrodes on the surface of the base body wherein a material of a first underlying electrode is copper and glass.

10. The electric component according to claim 1, further comprising underlying electrodes on the surface of the base body wherein a material of a first underlying electrode is mixture of silver and glass.

11. A film forming method for forming an alumina film on an outer surface of a base body, the film forming method comprising:
charging the base body into a first chamber that is capable of heating an internal atmosphere;
misting a raw material that is liquid and contains an aluminum atom and an oxygen atom into mist with an ultrasonic wave in a second chamber;
supplying the misted raw material from an inside of the second chamber into the first chamber together with a carrier gas; and
heating an inside of the first chamber to a first temperature while performing the supplying the misted raw material, and further second heating the inside of the first chamber to a second temperature defined as a temperature lower than the first temperature while performing the supply step after the first heating step.

12. The film forming method according to claim 11, wherein a composition ratio of atoms contained in the raw material is made constant during execution of the misting, the supplying, the first heating, and the second heating.

13. The film forming method according to claim 11, wherein the raw material is an organic salt containing aluminum or an organic solvent.

14. A film forming method for forming an alumina film on an outer surface of a base body, the film forming method comprising:
charging the base body into a first chamber that is capable of heating an internal atmosphere;
forming a raw material that is liquid and contains an aluminum atom and an oxygen atom into mist with a first ultrasonic wave with first frequency in a second chamber;
forming a raw material that is liquid and contains an aluminum atom and an oxygen atom into mist with a second ultrasonic wave with second frequency in a second chamber;
supplying the misted raw material from an inside of the second chamber into the first chamber together with a carrier gas; and
heating an inside of the first chamber.

15. The film forming method according to claim 11, wherein a composition ratio of atoms contained in the raw material is made constant during execution of the misting, the supplying, the first heating, and the second heating.
